(19) United States
(12) Patent Application Publication
(10) Pub. No.: US 2016/0379706 A1
(43) Pub. Date: Dec. 29, 2016

(54) DUAL VOLTAGE ASYMMETRIC MEMORY CELL

(71) Applicant: Intel Corporation, Santa Clara, CA (US)

(72) Inventors: Feroze A. MERCHANT, Austin, TX (US); Saurabh P. PRADHAN, Austin, TX (US); John R. RILEY, Spicewood, TX (US); Karthik SUBRAMANIAN, Austin, TX (US)

(21) Appl. No.: 15/039,830

(22) PCT Filed: Dec. 27, 2013
(86) PCT No.: PCT/US13/78113

§ 371 Date: May 26, 2016

(51) Int. Cl. G11C 11/419

(52) U.S. Cl. CPC G11C 11/419

(57) ABSTRACT

Memory with asymmetric power delivery for keeper cells in the memory are provided. In some embodiments, first and second power delivery circuits use separate first and second independently regulated power supplies. The first supply may be a supply nominally used for the memory structure, while the second supply may be lower than the first supply. In some embodiments, during a write operation, the first (higher) supply is used for one of the logic elements in a keeper cell, while the second (lower) supply is used for the other keeper logic element.

### BACKGROUND

The present invention relates generally to memory circuits, and in particular, relates to memory keeper cells.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1A shows a portion of a row of memory cells using a conventional weakened supply approach for mitigating against write contention.

FIG. 1B shows a keeper cell using cross-coupled inverters as its keeper logic elements.

FIG. 2A shows a portion of a row of memory cells with conventional, data-dependent, weakened supply circuitry.

FIG. 2B shows a keeper cell using cross-coupled inverters with bifurcated supplies.

FIG. 3 shows a portion of a row of memory cells with dual supply power delivery circuitry in accordance with some embodiments.

FIG. 4 is a table showing operational states for various elements in the circuit of FIG. 3 in accordance with some embodiments.

FIG. 5 shows the memory structure of FIG. 3 but with reduced retention supply circuitry in accordance with some embodiments.

FIG. 6 is a table showing operational states for various elements in the circuit of FIG. 5 for implementing a reduced power retention option in accordance with some embodiments.

### DETAILED DESCRIPTION

Designers continually seek to lower operational supply voltages to save power in VLSI devices. It may be particularly desirable to reduce operational voltages for memory cells used in register files, as well as for other memory structures in processors, since they typically occupy significant circuit resources. Unfortunately, memory reads and write operations may often be limiters for lowering the minimum required supply voltage (Vmin) for many memory circuits. Among other reasons, this may be due to charge contention in the memory's keeper cells when a new value is to be written into the cell.

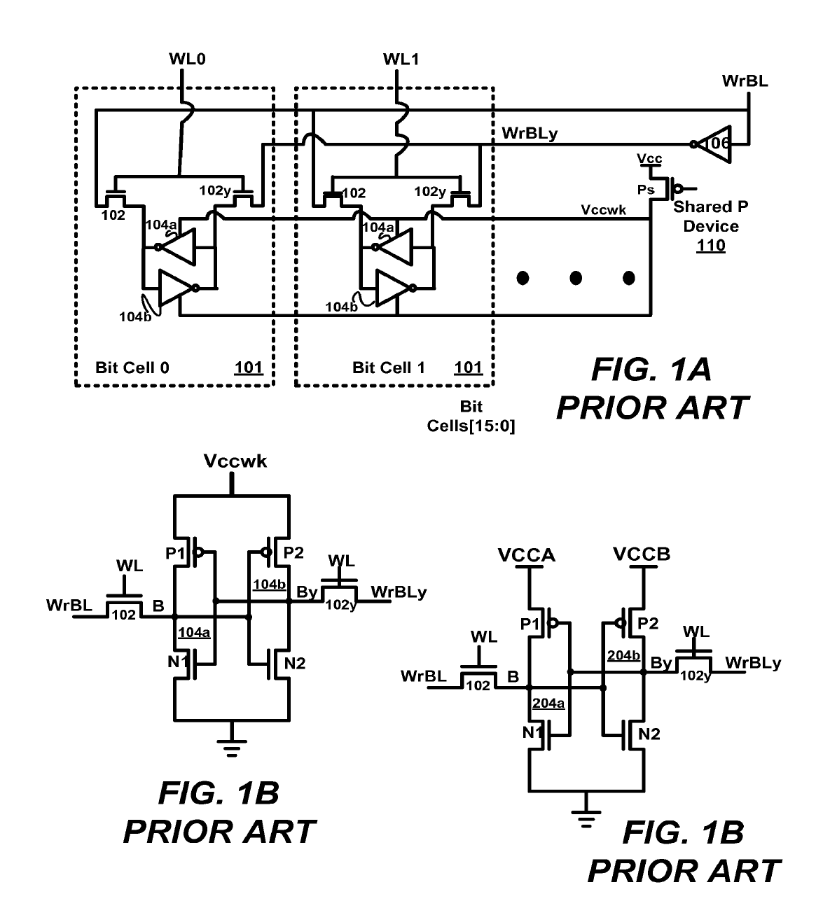

To illustrate this issue, FIG. 1A shows a portion of a typical memory structure with so-called “keeper” memory cells 101. (As used herein, the term “keeper” cell refers to any memory cell circuit that has two or more logic elements coupled together to store a complementary pair of bits, the logic elements contending against each other when the bits change state. For example, the logic elements could be inverters, as shown in FIGS. 1-3, individual transistors, NOR gates, NAND gates, and other devices.)

FIG. 1A shows a portion of a register file of keeper cells 101. Shown is a column (or slice) of cells 101, each associated with a different one of sixteen wordlines (15:0). (Not shown for convenience are other columns of the register file. For example, a register file might have 128 columns, e.g., with 128 data cells in each wordline.) Each cell 101 includes access devices 102, 102y and a pair of cross-coupled inverters 104, all coupled together as shown. The inverters are powered through a common supply provided by a shared device 110. For example, this shared device may be formed from one or more transistors such as P-type FETs that essentially serve to provide the keeper cells with weakened supplies (weakened versions of the memory Vcc). (Note that circuitry for reading data is not shown for convenience.)

The access devices 102, 102y for each cell are controlled by an associated wordline (WL0, WL1, etc.) that when asserted, turns on its associated access devices. At the same time, a digital value to be written into a selected cell is applied to write bitline (WrBL) and its complement is applied to write bitline bar (WrBLy). (An inverter 106 is included to generate the WLy value, the complement of the WL value.) The complementary bit pair value (WrBL, WrBLy) is then written into the selected cell and stored until a different value is written into the cell.

FIG. 1B shows an exemplary keeper cell 101, with access devices 102, 102y and cross-coupled inverters 104a, 104b, coupled as shown, to store complementary bits at nodes B, By, as indicated. Each inverter is formed from a P-type and an N-type FET, with their gates coupled to each other and their drains coupled to each other, as shown. If the complementary bit pair value to be written into the cell is different from the value currently being stored, then the transfer device driving the ’0 contends with the P device of the inverter whose output is storing the ’1. Until the P device turns off, it in effect “holds” the ’1, while the access device is trying to pull it down to a ’0. Once the access device (102) has drained enough charge, the bit cell starts to “flip”, and the P device (whose output is to be ’0) stops fighting the change, allowing the node to go to ’0 to complete the write operation. Supplying power to the keepers through the shared P device 110 weakens the keepers and thus, reduces contention during state (stored value) transitions. Unfortunately, however, the weakened supply also increases write completion times because it also weakens the P device for the inverter that is to output a ’1, and thus, limits available write performance.

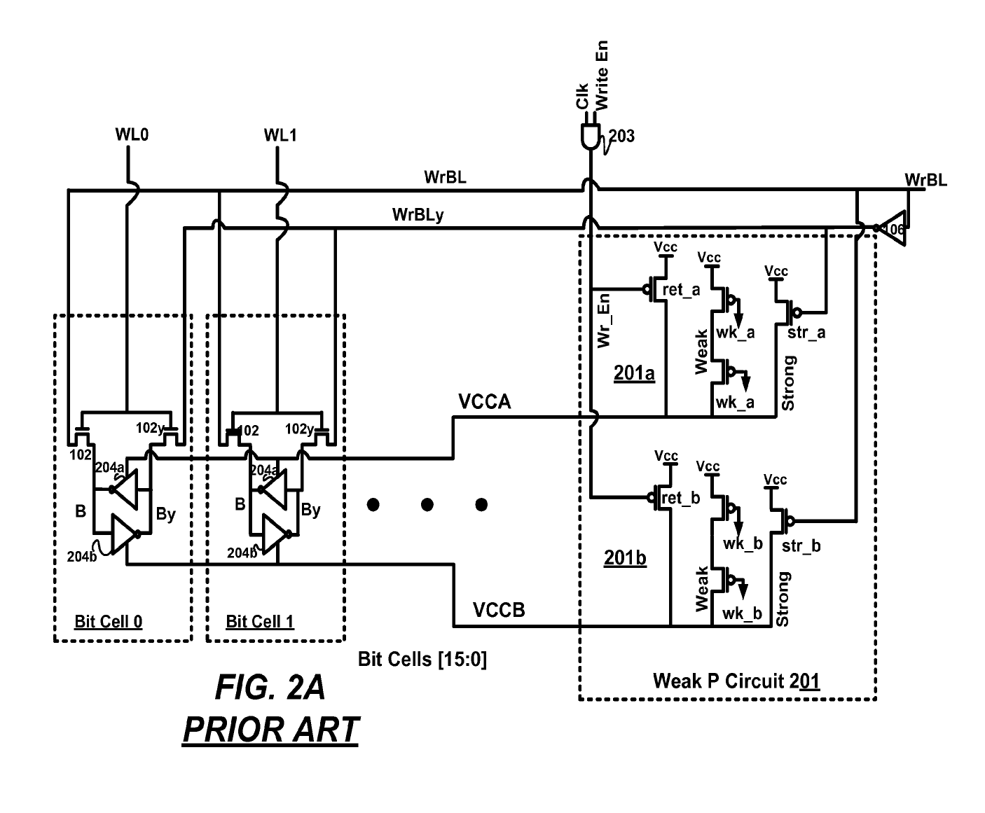

FIG. 2 illustrates a conventional approach to redressing this problem. Instead of using a weakened supply for the entire keeper cell in each cell of a memory structure, a weak P circuit 201 is employed to provide separate power sources (VCCA, VCCB) for each inverter in a keeper cell. Each of these sources can be either a weak or a strong level, depending on the value of the data to be written. A stronger power level is supplied to the inverter whose output is to go High in order to strongly turn on its P-type device for pulling up the ’1 at its output, while the lower supply is applied to the inverter driving the ’0 in order to weaken its P device. For example, if a memory cell “B” node is to go Low, then the VCCB supply source is made to be strongest, thereby supplying the 104b inverters with the stronger supply during a write operation.

The weak P circuitry 201 includes equivalent circuits, 201a and 201b, to provide power sources for the VCCA and VCCB supply lines, respectively. Each circuit includes three legs, a retention leg, a weak leg and a strong leg. The retention leg includes a relatively strong P-type device (ret_a or ret_b) that is turned on when a write operation is not occurring so as to maintain the cells at sufficient power levels to retain their stored states. The weak legs include a stack of weak P-type devices (wk_a or wk_b stacks) that are always turned on to provide constant weak supplies to the supply nodes (VCCA, VCCB). The strong legs each include a relatively strong P-type device (str_a, str_b). The str_a device is controlled by the WrBLy line, while the str_b device is controlled by the WrBL line. In this way, VCCB is the stronger power source when WrBL is to be Low, and VCCA is the stronger source when WrBLy is to be Low.

Thus, the conflict between the need for a weak keeper to reduce contention and the need for a strong keeper to enhance write completion may be redressed by decoupling the power supply sources for the cross-coupled inverters. The strength of the supply sources (VCCA and VCCB) is controlled by the value on WrBL and WrBLy. This control scheme alleviates contention on one side without compromising completion on the other side.

While the scheme of FIG. 2 is an improvement over the weakened, shared supply design of FIG. 1, the small stacked transistors (in the weak legs) of this scheme do not provide enough “weakening” to suitably or consistently reduce contention. It has been appreciated that another approach may be desired.

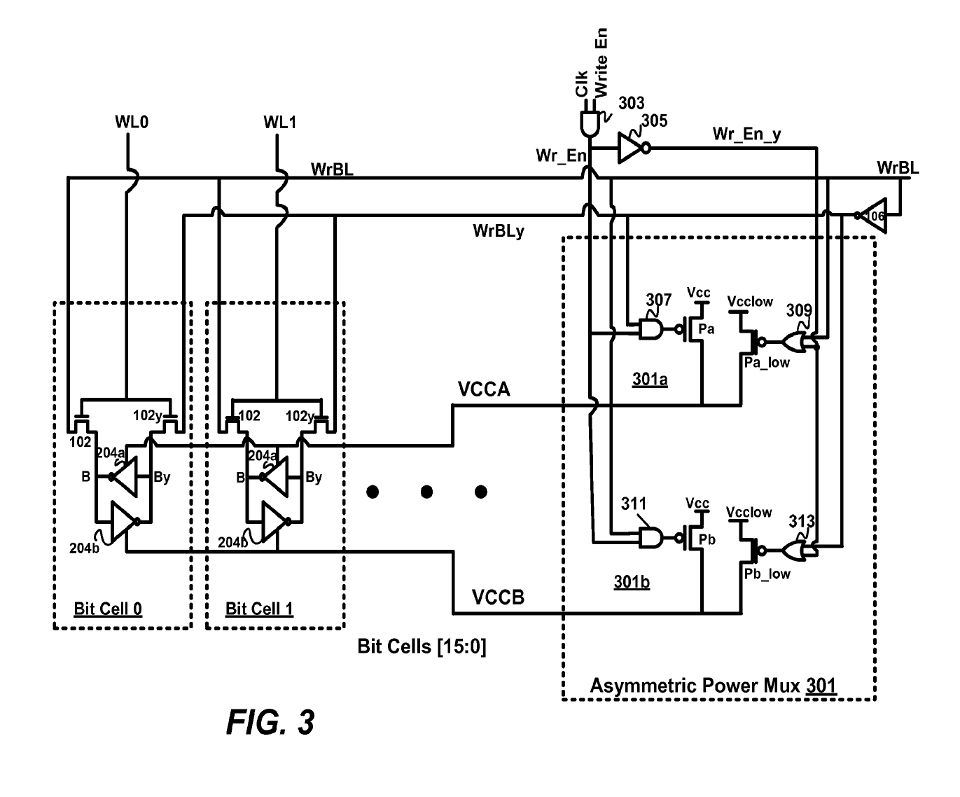

FIG. 3 shows a memory cell structure with asymmetric power delivery circuitry 301 including equivalent first and second circuits 301a, 301b for powering supply rails VCCA and VCCB, respectively. Also included is AND gate 303 and inverter 305, coupled as shown. In accordance with some embodiments, the circuits use separate first and second independently regulated power supplies. The first supply may be a supply nominally used for the memory structure, while the second supply (Vcclow) should be lower than the first supply, e.g., by 100 to 200 mV with contemporary CMOS processes. For example, separate on-die voltage regulators such as LDO (low drop out) regulators could be used to provide the first and second supplies, or at least a separate on-die regulator could be used for the lower (Vcclow) supply. It should be appreciated that any other suitable schemes such as charge sharing or charge coupling supplies could also be used to generate the lower power supply.

The first power delivery circuit 301a includes an AND gate 307, OR gate 309, and P-type devices Pa, Pa_low, all coupled together as shown. The P-type devices should be reasonably strong so as to suitably couple the Vcc and Vcclow supplies to the VCCA rail. AND gate 303 functions to synchronize a write enable signal (Write En) with a clock (Clk) to generate a Wr_En to enable (or control) a write operation. The Wr_En signal is coupled to an input of AND gate 307. The other input is coupled to the WrBLy line. The output of AND gate 307 controls P device Pa. The other P device (Pa_low) is controlled by OR gate 309, which has its inputs coupled to WrEn_y and WrBL, as shown.

Similarly, the second power delivery circuit 301b includes an AND gate 311, OR gate 313, and P-type devices Pb, Pb_low, all coupled together as shown. As with the first circuit, the P-type devices here should also be reasonably strong so as to suitably couple their supplies (Vcc, Vcclow) to the VCCB rail. The Wr_En signal is coupled to an input of AND gate 311. The other input is coupled to the WrBL line. The output of AND gate 311 controls P device Pb. The other P device (Pb_low) is controlled by OR gate 313, which has its inputs coupled to WrEn_y and WrBLy, as shown.

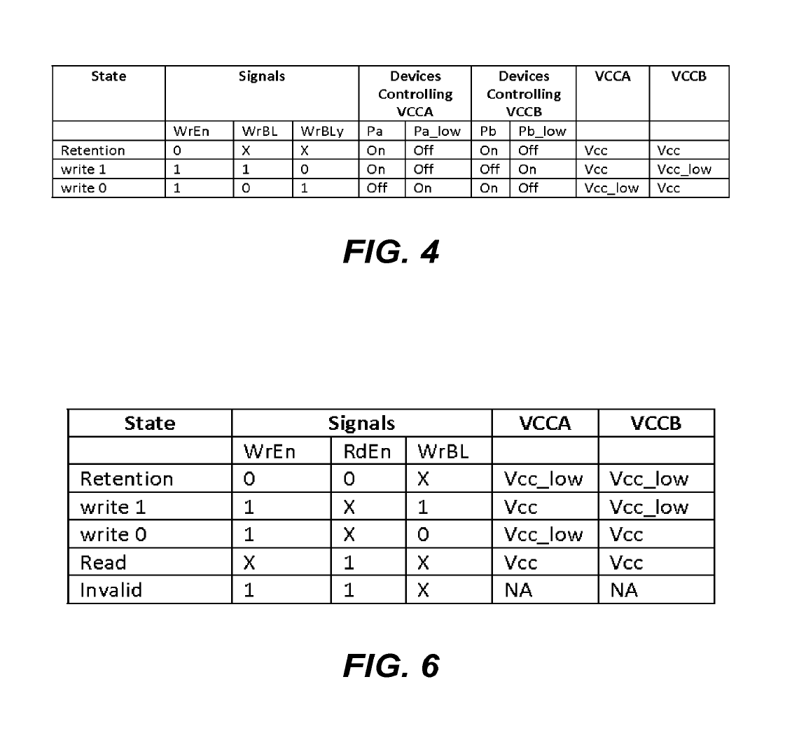

FIG. 4 is a table showing the signals and device states for the different operational states. During a nominal retention mode (typically, neither read nor write occurring), WrEn=0. Therefore, devices Pa and Pb are ON and VCCA=VCCB=Vcc. This ensures that the two sides of a bit cell (both keeper inverters) are sufficiently and symmetrically powered. During a write ’1 operation, WrEn=’1, WrBL=’1 and WrBLy=’0. This causes the VCCA power delivery circuit 301a to pass the higher supply voltage (VCCA=Vcc), while the VCCB power delivery circuit 301b passes the lower supply voltage (VCCB=Vcc_low). The condition (VCCB=Vcc_low) weakens the contending bit cell inverter (204b in a selected cell), allowing a ’0 value to be more readily passed through transfer gate 102b to the 204b output (By). Simultaneously, the condition that VCCA=Vcc causes the 204a inverter to effectively complete the write ’1 operation at its output (B). The write ’0 operation is complimentary to the write ’1 scenario, i.e., WrBL=’0 and WrBLy=’1, making VCCA=Vcc−low and VCCB=Vcc.

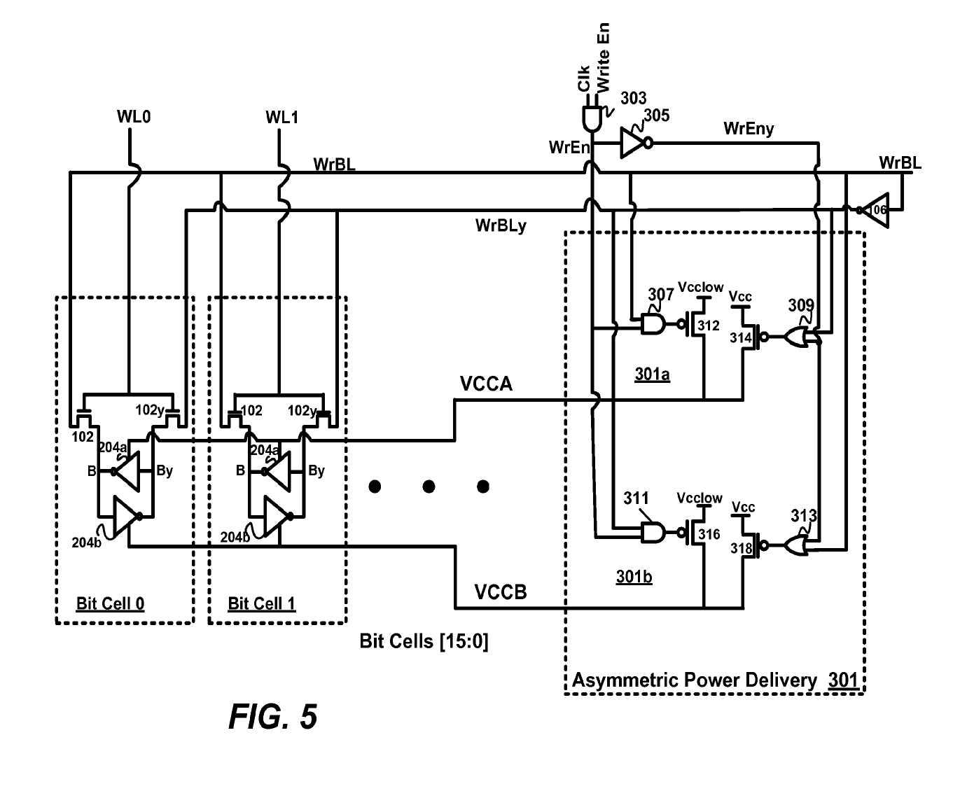

FIG. 5 shows a memory structure with asymmetric power delivery circuitry 501 that is similar to that of FIG. 3, except that during retention, the inverters are supplied with the Vcclow supply rather than the nominal Vcc supply. In some cases, the retention voltage, e.g., for a register file bit cell, can be lower than its active Vmin. Accordingly, in the depicted circuit, the Vcclow (instead of Vcc) is provided to both VCCA and VCCB during a retention state, e.g., when read and write operations are not being performed. This can reduce leakage power during retention states. However, in some implementations, it may require that VCCA and VCCB are charged back up from Vcclow to Vcc for a read operation. The table of FIG. 6 shows operational states, signals, and device states for the circuit of FIG. 5 in accordance with some embodiments.

In the preceding description, numerous specific details have been set forth. However, it is understood that embodiments of the invention may be practiced without these specific details. In other instances, well-known circuits, structures and techniques may have not been shown in detail in order not to obscure an understanding of the description. With this in mind, references to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the preceding description and following claims, the following terms should be construed as follows: The terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

The term “PMOS transistor” refers to a P-type metal oxide semiconductor field effect transistor. Likewise, “NMOS transistor” refers to an N-type metal oxide semiconductor field effect transistor. It should be appreciated that whenever the terms: “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs, material types, insulator thicknesses, gate(s) configurations, to mention just a few. Moreover, unless specifically referred to as MOS or the like, the term transistor can include other suitable transistor types, e.g., junction-field-effect transistors, bipolar-junction transistors, metal semiconductor FETs, and various types of three dimensional transistors, MOS or otherwise, known today or not yet developed.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

It should also be appreciated that in some of the drawings, signal conductor lines are represented with lines. Some may be thicker, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

It should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS, for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

1. A chip, comprising:
a group of keeper cells having first and second logic elements to store a complementary bit value;
a first power delivery circuit to provide one of a first and second regulated supplies to the first logic elements during a write operation based on the state of a complementary bit value to be written; and
a second power delivery circuit to provide the other of the first and second regulated supplies not provided by the first delivery circuit, said other supply to be provided to the second logic elements during the write operation, the second regulated supply to be smaller than the first regulated supply, the first and second delivery circuits to provide the first regulated supply to the first and second logic elements during a retention mode.

2. The chip of claim 1, in which the second regulated supply is at least 100 mV less than the first regulated supply.

3. The chip of claim 1, in which the first and second logic elements include inverters.

4. The chip of claim 1, in which the first and second logic elements include individual transistors.

5. The chip of claim 1, in which the group of keeper cells constitutes a register file in a processor.

6. A chip, comprising:
a group of keeper cells having first and second logic elements to store a complementary bit value;
a first power delivery circuit to provide one of a first and second regulated supplies to the first logic elements during a write operation based on the state of a complementary bit value to be written; and
a second power delivery circuit to provide the other of the first and second regulated supplies not provided by the first delivery circuit, said other supply to be provided to the second logic elements during the write operation, the second regulated supply to be smaller than the first regulated supply, the first and second delivery circuits to provide the second regulated supply to the first and second logic elements during a retention mode.

7. The chip of claim 6, in which the second regulated supply is at least 100 mV less than the first regulated supply.

8. The chip of claim 6, in which the first and second logic elements include inverters.

9. The chip of claim 6, in which the first and second logic elements include individual transistors.

10. The chip of claim 6, in which the group of keeper cells constitutes a register file in a processor.

11. The chip of claim 6, the first and second delivery circuits to transition from the second to the first regulated supplies when a read operation is to occur.

12. An apparatus comprising:
an static random access memory (SRAM) bit cell having first and second inverters which are cross-coupled;
a first power supply node coupled to the first inverter;
a second power supply node coupled to the second inverter; and
logic to raise or lower voltage levels on the first and/or second power supply nodes according to an operation mode.

13. The apparatus of claim 12 comprises:
a first voltage regulator to provide a first power supply to the first power supply node; and
a second voltage regulator to provide a second power supply to the second power supply node.

14. The apparatus of claim 13, wherein the first power supply is different from the second power supply.

15. The apparatus of claim 13, wherein the first power supply and the second power supply is at least 100 mV less than or greater than the other.

16. The apparatus of claim 13, wherein the first and second voltage regulators are first and second low drop-out (LDO) regulators, respectively.

17. The apparatus of claim 12, wherein the operation mode is one of: read mode, write mode, retention mode.
